(19) United States
(12) Patent Application Publication
(10) Pub. No.: US 2026/0344309 A1
(43) Pub. Date: Oct. 29, 2026

(54) DUAL ATOMIC LAYER AREA SELECTIVE DEPOSITION

(71) Applicant: UCHICAGO ARGONNE, LLC, Chicago, IL (US)

(72) Inventors: Jeffrey W. ELAM, Elmhurst, IL (US); Chi Thang NGUYEN, Westmont, IL (US); Angel YANGUAS-GIL, Northbrook, IL (US)

(73) Assignee: UCHICAGO ARGONNE, LLC, Chicago, IL (US)

(21) Appl. No.: 19/548,181

(22) Filed: Feb. 24, 2026

Related U.S. Application Data
(60) Provisional application No. 63/796,028, filed on Apr. 28, 2025.

(51) Int. Cl. H10P 14/60; C23C 16/04; C23C 16/18; C23C 16/40; C23C 16/455; C23C 16/56; H10P 14/692; H10P 50/28

(52) U.S. Cl. CPC H10P 14/6339; C23C 16/04; C23C 16/18; C23C 16/401; C23C 16/402; C23C 16/45542; C23C 16/45553; C23C 16/56; H10P 14/668; H10P 14/6682; H10P 14/6939; H10P 50/283

(57) ABSTRACT

A method of area selective deposition includes (A) providing a substrate comprising a first area terminated with first reactive groups and a second area terminated with second reactive groups; (B) contacting the substrate with a first precursor reactive with first reactive groups to form a first intermediate on the first area; (C) contacting the substrate with a second precursor reactive with second reactive groups to form a second intermediate on the second area; and (D) contacting the substrate with a first co-reactant, the co-reactant reactive with the second intermediate, forming a first thin film on the second area.

### CROSS-REFERENCE TO RELATED APPLICATIONS

This application claims the benefit of and priority to U.S. Provisional Patent Application No. 63/796,028, filed Apr. 28, 2025, the entire contents of which are incorporated herein by reference.

### GOVERNMENT RIGHTS

This invention was made with government support under Contract No. DE-AC02-06CH11357 awarded by the United States Department of Energy to UChicago Argonne, LLC, operator of Argonne National Laboratory. The government has certain rights in the invention.

### TECHNICAL FIELD

The present technology is generally related to thin film deposition, and more specifically is related to area selective deposition of thin films.

### BACKGROUND

Conventionally, semiconductor chips and electronic devices are fabricated through a complex multi-step process that may include film deposition on a substrate, lithography on the deposited film, and selective etching of the deposited film.

### SUMMARY

In an aspect, a method of area selective deposition is disclosed. The method includes (A) providing a substrate comprising a first area terminated with a first reactive group and a second area terminated with a second reactive group; (B) contacting the substrate with a first precursor reactive with the first reactive group to form a first intermediate on the first area; (C) contacting the substrate with a second precursor reactive with the second reactive group to form a second intermediate on the second area; and (D) contacting the substrate with a first co-reactant, the co-reactant reactive with the second intermediate, forming a first thin film on the second area.

The first reactive groups and the second reactive groups may be different. The first reactive groups may be hydroxyl groups. The second reactive groups may include hydrogen (e.g., Si—H), metal, or a combination thereof.

The method may include contacting the substrate with a reduction reactant, the reduction reactant reactive with the first thin film to reduce the first thin film. The method may include (E) contacting the substrate with a second co-reactant, the second co-reactant reactive with the first intermediate, forming a second thin film on the first area.

The first precursor may include a silicon precursor; the second precursor may include a ruthenium precursor, a hafnium precursor, an aluminum precursor, or a combination thereof; the first co-reactant may include water, oxygen, or a combination thereof; and the second co-reactant may include oxygen plasma, ozone, or a combination thereof. The silicon precursor may include bis(N,N-dimethylamino)dimethylsilane (DMADMS). The second precursor may include the ruthenium precursor and the ruthenium precursor comprises dicarbonyl-bis(5-methyl-2,4-hexanediketonato)ruthenium (II), bis(ethylcyclopentadienyl)ruthenium (II), tricarbonyl (η4-2-methylene-1,3-propanediyl)ruthenium (II), or a combination of any two or more thereof. The second precursor may include the hafnium precursor, and the hafnium precursor may include tetrakis (dimethylamino) hafnium (TDMAH). The second precursor may include the aluminum precursor, the aluminum precursor comprising dimethylaluminum isopropoxide (DMAI).

The first precursor may include a tungsten precursor, the second precursor may include a ruthenium precursor, a hafnium precursor, or a combination thereof; the first co-reactant may include water, oxygen, or a combination thereof; and the second co-reactant may include Ar/H₂ plasma. The tungsten precursor may include ethylcyclopentadienyltungsten (V) tricarbonyl hydride (HEtCpW(CO)₃).

The first precursor may include a titanium precursor; the second precursor may include a ruthenium precursor, a hafnium precursor, or a combination thereof, the first co-reactant may include water, oxygen, or a combination thereof; and the second co-reactant may include oxygen plasma, ozone, or a combination thereof. The titanium precursor may include trimethoxy-(pentamethylcyclopentadienyl) titanium (IV) (TMPMCT).

The method may include (F) contacting the substrate with a second co-reactant, the second co-reactant reactive with the first intermediate, forming a second thin film on the first area. The first precursor may include a titanium precursor; the second precursor may include a ruthenium precursor, a hafnium precursor, or a combination thereof; the first co-reactant may include water, oxygen, or a combination thereof; and the second co-reactant may include oxygen plasma, ozone, or a combination thereof.

The method may include repeating steps (A) to (E) a plurality of times to deposit the first thin film on the second area and the second thin film on the first area.

In an aspect, a method of forming particles is disclosed. The method includes (A) contacting a substrate terminated with a plurality of first reactive groups with a first precursor to form a plurality of first intermediates on a first portion of the substrate; (B) contacting the substrate with a second precursor to form a plurality of second intermediates on a second portion of the substrate, the second portion different from the first portion, and the second precursor comprising a metal; (C) contacting the substrate with a first co-reactant reactive with the plurality of second intermediates to form a second oxide on the second portion, the second oxide comprising a metal oxide; and (D) contacting the substrate with reduction reactant to reduce the second oxide to metal, forming a plurality of metallic particles on the second portion of the substrate.

In the method of forming particles, step (C) may further include reacting the first co-reactant with the plurality of first intermediates to form a first oxide on the first portion; and the method may further include (E) contacting the substrate with the first precursor to form a plurality of third intermediates on the first oxide; (F) contacting the substrate with the second precursor to form a plurality of fourth intermediates on the plurality of metallic particles; (G) contacting the substrate with the first co-reactant reactive with the plurality of third intermediates to form a third oxide on the first oxide and reactive with the plurality of fourth intermediates to form a fourth oxide on the plurality of metallic particles; the fourth oxide comprising a metal oxide; and (H) contacting the substrate with reduction reactant to reduce the fourth oxide to metal, increasing a dimension of the plurality of metallic particles on the second portion of the substrate. The method may include repeating steps (E) to (H) a plurality of times to increase the dimension of the plurality of metallic particles. The first precursor may include a silicon precursor; the second precursor may include a ruthenium precursor, a hafnium precursor, or an aluminum precursor; the first co-reactant may include ozone; and the second co-reactant may include ozone.

In the method of forming particles, the first co-reactant in step (C) may be non-reactive or only partially reactive with the first intermediates, and the method may further include (E) contacting the substrate with the second precursor to form a plurality of fourth intermediates on the plurality of metallic particles; (F) contacting the substrate with the first co-reactant reactive with the plurality of fourth intermediates to form a third oxide on the plurality of metallic particles; the third oxide comprising a metal oxide; and (G) contacting the substrate with reduction reactant to reduce the third oxide to metal, increasing a dimension of the plurality of metallic particles on the second portion of the substrate. The method may include repeating steps (E) to (G) a plurality of times to increase the dimension of the plurality of metallic particles. The method may further include (H) contacting the substrate with a second co-reactant reactive with the plurality of first intermediates to form a fourth oxide on the first portion of the substrate. The first precursor may include a silicon precursor; the second precursor may include a ruthenium precursor, a hafnium precursor, or an aluminum precursor; the first co-reactant may include oxygen; the second co-reactant may include O₃, and the reduction reductant may include hydrogen.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE DRAWINGS

FIG. 1 is a flow diagram of a process of dual atomic layer area selective deposition.

FIG. 2 is an illustration of another process of dual atomic layer area selective deposition.

FIG. 3 is a flow diagram of a process of forming metallic nanoparticles.

FIG. 4 is an illustration of another process of forming metallic nanoparticles.

FIG. 5 is an illustration of a process of etching a ruthenium film.

FIGS. 6A-6F provide characterization of ruthenium deposition. FIG. 6A is a graph of growth per cycle (GPC) of ruthenium at different temperatures. FIG. 6B is a graph of deposited ruthenium thickness with number of deposition cycles. FIG. 6C is a graph of GPC of ruthenium with length of ruthenium precursor exposure. FIG. 6D is a graph of GPC of ruthenium with length of oxygen exposure. FIG. 6E is a cross-sectional image of the ruthenium film acquired with scanning electron microscopy (SEM). FIG. 6F is atomic force microscopy (AFM) characterization of the roughness of the ruthenium film.

FIGS. 7A-7C provide characterization of ruthenium area selective deposition (ASD).

FIG. 7A is a graph of water contact angle (WCA) on a silicon substrate with duration of exposure to bis(N,N-dimethylamino)dimethylsilane (DMADMS). FIG. 7B is a graph of selectivity with length of exposure of bis(N,N-dimethylamino)dimethylsilane (DMADMS). FIG. 7C is a graph of selectivity with number of deposition cycles.

FIG. 8 is a graph of silicon oxide thickness with number of silicon oxide deposition cycles.

FIGS. 9A-9C provide characterization of ruthenium etching by ozone. FIG. 9A is a graph of etch rate at different temperatures. FIG. 9B is a graph of etched thickness with length of ozone exposure. FIG. 9C provides AFM characterization of the roughness of the etched ruthenium.

### DETAILED DESCRIPTION

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s).

As used herein, “about” will be understood by persons of ordinary skill in the art and will vary to some extent depending upon the context in which it is used. If there are uses of the term which are not clear to persons of ordinary skill in the art, given the context in which it is used, “about” will mean up to plus or minus 10% of the particular term.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

To improve the performance of semiconductor chips and electronic devices, structure design has transitioned from 2D structures to 3D structures. Conventionally, methods such as film deposition, lithography, and etching are utilized to form 2D and 3D structures. However, these conventional methods may include complex multi-step processes, with longer processing times. Furthermore, as device sizes continue to shrink, overcoming technological limits becomes increasingly challenging.

Conventional methods of patterning thin films suffered from deposition errors, such edge placement error (EPE) and lateral growth. EPE is a metric measuring the difference between the intended position and the actual position of the deposited film. EPE may be a factor in the performance and device failure of semiconductor chips and electronic devices. Lateral growth is the thin film deposited beyond the mask boundary during conventional methods of forming semiconductor chips and electronic devices. Lateral growth may decrease the likelihood of success of forming semiconductor chips and electronic devices, for example where the substrate has a high aspect ratio (e.g., greater than 10:1).

Metal nanoparticles (NPs) are useful in many applications, including catalysis, electronics, optics, and energy storage devices. However, their use in certain applications may be limited by the ability to form a high density of NPs with a narrow particle size distribution (PSD). Achieving a high density of NPs with a narrow PSD may depend on size-selected NPs to fine-tune nucleation. Conventional methods of forming nanoparticles typically result in a broad size distribution with random spacing.

Disclosed herein are processes for dual area selective deposition (ASD) of thin films. These processes may be useful for manufacturing 2D and 3D structures, including advanced semiconductor chips and electronic devices. Using dual ASD, different materials may be deposited simultaneously in a single process, following a bottom-up approach. This process may prevent or reduce instances of deposition errors, such as EPE and lateral growth.

Dual ASD may provide size-selected NPs. In particular, dual ASD may provide a high density of NPs with a narrow PSD in a predetermined area of a substrate, ability to fine-tune the particle size, and ability to tune the spacing between NPs.

Deposition disclosed herein may be vapor-phase deposition. The vapor-phase deposition may be used to form a thin (e.g., a thickness of less than 100 nm, less than 5 nm, or less than 2 nm) coating. Nonlimiting examples of the coatings may include a metal, metal oxide, silicon, silicon dioxide, or a combination of any two or more thereof.

The vapor-phase deposition may be chemical vapor deposition (CVD). For example, the CVD may be atomic layer deposition (ALD). ALD is a scalable, vapor phase self-limiting thin film deposition technique. The ALD coating may be continuous and conformally deposited on surfaces of the substrate, including on high-aspect ratio substrates.

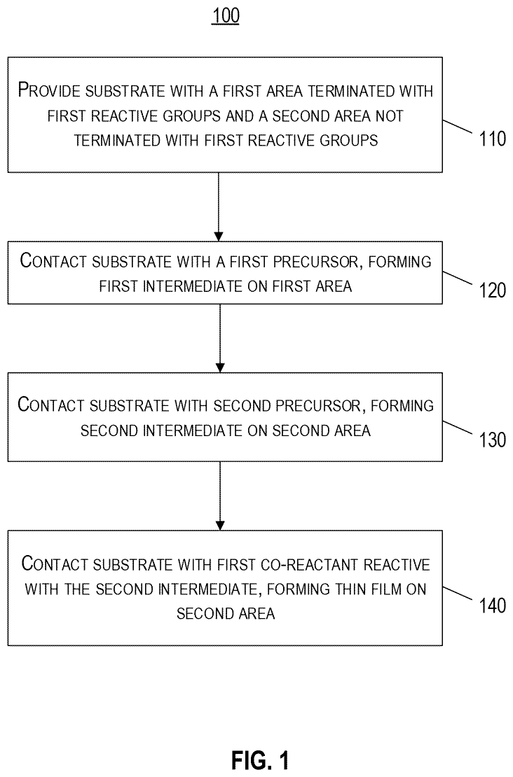

In an aspect, a method of area selective deposition is disclosed. FIG. 1 is a flow diagram of a process 100 of dual atomic layer area selective deposition. The process 100 includes step 110 of providing a substrate including a first area terminated with first reactive groups (e.g., hydroxyl groups) and a second area not terminated with first reactive groups. The second area may be terminated with second reactive groups (e.g., hydrogen, metal, or a combination thereof). Step 110 may include providing the substrate within an ALD reactor.

The substrate may be any material that includes a first area terminated with a first reactive group (e.g., hydroxyl group) and a second area not terminated with first reactive group. For example, the first area may be terminated with an oxide of the material and the second area may be terminated with metallic groups and/or hydrogen groups. Nonlimiting examples of the first area material include, but are not limited to, silicon dioxide, germanium oxide, gallium oxide, aluminum oxide, indium oxide, indium-doped tin oxide, zinc oxide, tin oxide, borosilicate glass, lead glass, soda lime glass, or a combination of any two or more thereof. Nonlimiting examples of the second area material include, but are not limited to, silicon, silicon nitride, ruthenium, germanium, gallium, aluminum, indium, indium-doped tin, zinc, tin, graphene, or a combination of any two or more thereof. As an example, the substrate may be silicon, where the first area includes a native silicon dioxide or a thermal silicon dioxide, and the second area includes hydrogen-terminated silicon. As an example, the hydrogen-terminated silicon may be formed via area-selective treatment with hydrofluoric acid.

Steps 120-140 as described herein may be conducted in a reactor. Typically, the ALD process takes place in a uniform temperature-controlled reactor. In some embodiments, the substrate may be heated to a predetermined temperature during the ALD process. For example, the first predetermined temperature may be in the range of 100 °C-350 °C (e.g., 100, 110, 120, 130, 140, 150, 160, 170, 180, 190, . . . 350 °C, inclusive of all ranges and values therebetween). In some embodiments, the predetermined temperature is in the range of 200-300 °C (e.g., 240 °C). Temperature also impacts the overall energy in the system and the performance for diffusion and/or reaction. In a given ALD process, the deposition temperature range may be the temperature range in which ALD deposition occurs at an approximately static growth rate as function of temperature, which is referred to as the “ALD window.” The ALD reaction may occur at a temperature of the precursor sufficient to provide an approximately constant precursor evaporation rate (i.e., vapor pressure). If the precursor vapor pressure is insufficient to react with the reactive surface sites, there may still be layer growth, but the surface coverage may be less complete due to incomplete precursor saturation. If the vapor pressure is too high, precursor may be wasted, and CVD growth may occur if there is not sufficient purge time to remove the excess precursor. The temperature of the layer growth can be as low as the subliming or evaporation temperature of the ALD precursors. For example, if a precursor sublimes at 150 °C, films may be grown around that temperature or a temperature higher than the sublimation temperature. Generally, layer growth temperature may be at least 10-50 °C higher than the precursor sublimation temperature. Further, a plasma may be used as the co-reactant or to enhance the growth rate or tailor the composition of the deposited layer or make the deposited material crystalline.

The process 100 includes step 120 of contacting the substrate with a first precursor, forming a first intermediate on the first area of the substrate. The first precursor may be, for example, a material reactive or adsorbable on the first area of the substrate to form the first intermediate. The first precursor may react with a first reactive group on the substrate surface and not reactive with a second reactive group on the substrate. The first reactive group and the second reactive group may be different. The first reactive groups may be present only on the first area of the substrate. For example, the first reactive groups may be hydroxyl groups and the second reactive groups may be hydrogen groups (e.g., Si—H groups) and/or metallic groups. For example, the first precursor may react with hydroxyl groups on the substrate surface but not react with hydrogen groups (e.g., Si—H groups) or metallic groups.

Contacting the substrate with the first precursor may include introducing the first precursor into a reactor via a first precursor vapor pulse for an exposure time, followed by a purge, such as where the reactor is pumped to a vacuum to remove excess first precursor.

The first precursor may be a vapor and the first precursor pulse may introduce the first precursor vapor into the reactor for a first precursor pulse time of a few milliseconds to tens of seconds (e.g., 0.005, 0.01, 0.05, 0.1, 0.5, 1, 5, 10, 20, or 30 seconds, inclusive of all ranges and values therebetween). The first partial pressure of the first precursor pulse may be in the range of 0.01-1000 Torr (e.g., 10, 25, 50, 75, 100, 500, or 1000 Torr, inclusive of all ranges and values therebetween), such as, for example, at least 0.5-100 Torr. One of skill in the art will appreciate that the time length, pressure, and amount of precursor for the pulse are all factors in determining the overall amount for each of those operation parameters. For example, the pressure and amount may follow from the duration of the pulse but depend on the size of the chamber and the type of valve as would be understood from general knowledge regarding ALD. Note, for ease of reference herein, the process is described with regard to the pulse duration, but it should be understood that the precursor partial pressure is another means to control the precursor dose. For spatial ALD, the precursor exposure is controlled by the amount of time the substrate spends in the precursor spatial domain and the precursor partial pressure in the precursor spatial domain. A carrier gas, such as argon or other non-reactive (with the substrate or the precursors) gas, may be used.

The first precursor exposure may include exposing the substrate to the first precursor for a first exposure time and a first partial pressure of the first precursor so that the first precursor binds with the substrate in the first area or a coating from prior ALD cycles on the first area of the substrate. In some embodiments, given the brief time for the pulse/exposure for the ALD process the pulse lasts the entire exposure until the purge starts with the pulse time and exposure time being the same. The first precursor pulse time may be less than the first exposure time, or they may be equal such that the exposure is the same as the pulse. The first exposure time may be in the range of 0.5-500 seconds (e.g., 0.5, 1, 5, 10, 20, 30, 40, 50, 60, 70, 80, 90, 100, 120, 140, 160, 180, 200, 220, 240, 260, 280, 300, 350, 400, 450 or 500 seconds or several minutes, inclusive of all ranges and values therebetween). In some embodiments, the first predetermined time is in the range of 1-10 seconds. The first partial pressure of the first precursor may be in the range of 0.01-10 Torr (e.g., 0.01, 0.05, 0.1, 0.5, 1.0, 5.0, or 10 Torr, inclusive of all ranges and values therebetween). The first partial pressure of the first precursor may be in the range of 0.1-1 Torr. ALD growth may also be performed at various reactor pressures (e.g., 10⁻⁴ Torr to 1000 Torr).

The first precursor purge evacuates unreacted precursor from the reactor. The first precursor purge may be for a first precursor purge time of 0.5-30 seconds (e.g., 0.5, 1, 5, 10, 20, or 30 seconds, inclusive of all ranges and values therebetween), such as 15 seconds. The first precursor purge may evacuate the reactor such that the total pressure in the reactor is reduced substantially to vacuum. Alternatively, the first precursor purge may consist of a constant flow of high purity carrier gas at a constant pressure that sweeps the unreacted precursor from the reactor. In either case, the first precursor purge reduces the partial pressure of the precursor in the reactor by a factor of 10² to >10⁹ (e.g., from an initial value of 1 Torr immediately following the first precursor exposure to a final value after the first precursor purge of 10⁻² to <10⁻⁹ Torr).

The process 100 includes step 130 of contacting the substrate with a second precursor, forming a second intermediate on a second area of the substrate. The second precursor may react with second reactive groups on the substrate surface. The second reactive groups may be present in the second area of the substrate. For example, the second reactive groups may include hydrogen groups (e.g., Si—H groups), metallic groups, or the combination thereof. For example, the second precursor may be reactive with hydrogen groups (e.g., Si—H groups), metallic groups, or both hydrogen groups and metallic groups.

Contacting the substrate with the second precursor may include introducing the second precursor to the reactor via a second precursor pulse for a second precursor exposure time, followed by a second precursor purge.

The second precursor may be a vapor and the second precursor pulse may introduce the second precursor vapor into the reactor for a second precursor pulse time of a few milliseconds to tens of seconds (e.g., 0.005, 0.01, 0.05, 0.1, 0.5, 1, 5, 10, 20, or 30 seconds, inclusive of all ranges and values therebetween). The partial pressure of the second precursor pulse may be in the range of 0.01-1000 Torr (e.g., 10, 25, 50, 75, 100, 500, or 1000 Torr, inclusive of all ranges and values therebetween), such as, for example, at least 0.5-100 Torr. One of skill in the art will appreciate that the time length, pressure, and amount of precursor for the pulse are all factors in determining the overall amount for each of those operation parameters. For example, the pressure and amount may follow from the duration of the pulse but depend on the size of the chamber and the type of valve as would be understood from general knowledge regarding ALD. Note, for ease of reference herein, the process is described with regard to the pulse duration, but it should be understood that the precursor partial pressure is another means to control the precursor dose. For spatial ALD, the precursor exposure is controlled by the amount of time the substrate spends in the precursor spatial domain and the precursor partial pressure in the precursor spatial domain. A carrier gas, such as argon or other non-reactive (with the substrate or the precursors) gas, may be used.

The second precursor exposure may include exposing the substrate to the second precursor for a second exposure time and a second partial pressure of the second precursor so that the second precursor binds with the substrate in the second area or a coating from prior ALD cycles on the second area of the substrate. In some embodiments, given the brief time for the pulse/exposure for the ALD process the pulse lasts the entire exposure until the purge starts with the pulse time and exposure time being the same. The second precursor pulse time may be less than the second exposure time, or they may be equal such that the exposure is the same as the pulse. The second exposure time may be in the range of 0.5-500 seconds (e.g., 0.5, 1, 5, 10, 20, 30, 40, 50, 60, 70, 80, 90, 100, 120, 140, 160, 180, 200, 220, 240, 260, 280, 300, 350, 400, 450 or 500 seconds or several minutes, inclusive of all ranges and values therebetween). In some embodiments, the second predetermined time is in the range of 1-10 seconds. The second partial pressure of the second precursor may be in the range of 0.01-10 Torr (e.g., 0.01, 0.05, 0.1, 0.5, 1.0, 5.0, or 10 Torr, inclusive of all ranges and values therebetween). The second partial pressure of the second precursor may be in the range of 0.1-1 Torr. ALD growth may also be performed at various reactor pressures (e.g., 10⁻⁴ Torr to 1000 Torr).

The second precursor purge evacuates unreacted precursor from the reactor. The second precursor purge may be for a second precursor purge time of 0.5-30 seconds (e.g., 0.5, 1, 5, 10, 20, or 30 seconds, inclusive of all ranges and values therebetween), such as 15 seconds. The second precursor purge may evacuate the reactor such that the total pressure in the reactor is reduced substantially to vacuum. Alternatively, the second precursor purge may consist of a constant flow of high purity carrier gas at a constant pressure that sweeps the unreacted precursor from the reactor. In either case, the second precursor purge reduces the partial pressure of the precursor in the reactor by a factor of 10² to >10⁹ (e.g., from an initial value of 1 Torr immediately following the second precursor exposure to a final value after the second precursor purge of 10⁻² to <10⁻⁹ Torr).

The process 100 includes step 140 of contacting the substrate with a first co-reactant reactive with the second intermediate, forming a first thin film on the second area.

Contacting the substrate with the second precursor may include introducing the co-reactant to the reactor via a co-reactant pulse for a co-reactant exposure time, followed by a co-reactant purge.

The substrate may be exposed to a first co-reactant. The first co-reactant is reactive with the second precursor adsorbed on the substrate or reactive intermediates (also called reactive species or adsorbates) resulting from the second precursor's reaction with the substrate adsorbed on the substrate or reactive species (e.g., precursor complex) resulting from the first precursor's reaction with the substrate. The first co-reactant is introduced into the reactor for a first co-reactant exposure time and at a partial pressure of the first co-reactant so that first co-reactant reacts with the surface sites formed by the second precursor reacting with the substrate (or previous ALD deposited coatings). The first co-reactant exposure time may be in the range of 0.5-500 seconds (e.g., 0.5, 1, 5, 10, 20, 30, 40, 50, 60, 70, 80, 90, 100, 120, 140, 160, 180, 200, 220, 240, 260, 280, 300, 350, 400, 450 or 500 seconds, inclusive of all ranges and values therebetween), such as about 1 second. The second partial pressure of the first co-reactant can be in the range of 0.01-10 Torr (e.g., 0.01, 0.05, 0.1, 0.5, 1.0, 5.0, or 10 Torr, inclusive of all ranges and values therebetween). In some embodiments, the second partial pressure of the first co-reactant is in the range of 0.1-1 Torr (e.g., about 0.5 Torr or 0.88 Torr). ALD growth can also be performed in various reactor pressures (10⁻⁴ Torr to 1000 Torr).

The first co-reactant purge evacuates unreacted co-reactant from the reactor. The first co-reactant purge may be for a first co-reactant purge time of 0.5-500 seconds (0.5, 1, 5, 10, 20, 30, 40, 50, 60, 70, 80, 90, 100, 120, 140, 160, 180, 200, 220, 240, 260, 280, 300, 350, 400, 450 or 500 seconds, inclusive of all ranges and values therebetween), such as 10 seconds. The first co-reactant purge may evacuate the reactor such that the total pressure is reduced substantially to vacuum. Alternatively, the first co-reactant purge may consist of a constant flow of high purity carrier gas at a constant pressure that sweeps the unreacted co-reactant from the reactor. In either case, the first co-reactant purge reduces the partial pressure of the co-reactant in the reactor by a factor of 10² to >10⁹ (e.g., from an initial value of 1 Torr immediately following the first co-reactant exposure to a final value after the first co-reactant purge of 10⁻² to <10⁻⁹ Torr).

The first co-reactant may be reactive only with the second intermediate and not reactive with the first intermediate. In this case, the step 140 may form the first thin film on the second area and not on the first area. Alternatively or additionally, the first co-reactant may be reaction with the second intermediate and the first intermediate, forming a first thin film on the second area and a second thin film on the second area.

It should be appreciated that the dose and purge time may be based on the self-limiting behavior of the precursors/co-reactants and the desired precursor utilization efficiency. The exposure time can be varied in a wide range from a few milliseconds to tens of seconds. Further if a longer dose than purge time is utilized, the times may be increased to avoid a CVD-type reaction, which can result in non-uniformity and particle formation. The ALD process may be a spatial ALD process in which the substrate moves between spatially separated domains of precursors and co-reactants separated by domains of inert gas purge.

The process 100 may further include additional steps. The process 100 may include the step, after step 130 or step 140, of contacting the substrate with a reduction reactant, the reduction reactant reactive with the first thin film to reduce the first thin film, the second thin film, or the combination thereof. This step may be part of 1 cycle of ASD. For example, the reduction reactant may reduce the first thin film from an oxide or hydroxide film to an elemental film. For example, the first thin film may be a metal oxide and this step may reduce the metal oxide film to a metallic film.

The reduction reactant may be a vapor and the reduction reactant pulse may introduce the reduction reactant vapor into the reactor for a reduction reactant pulse time of a few milliseconds to tens of seconds (e.g., 0.005, 0.01, 0.05, 0.1, 0.5, 1, 5, 10, 20, or 30 seconds, inclusive of all ranges and values therebetween). The partial pressure of the reduction reactant pulse may be in the range of 0.01-1000 Torr (e.g., 10, 25, 50, 75, 100, 500, or 1000 Torr, inclusive of all ranges and values therebetween), such as, for example, at least 0.5-100 Torr. One of skill in the art will appreciate that the time length, pressure, and amount of reduction reactant for the pulse are all factors in determining the overall amount for each of those operation parameters. For example, the pressure and amount may follow from the duration of the pulse but depend on the size of the chamber and the type of valve as would be understood from general knowledge regarding ALD. Note, for ease of reference herein, the process is described with regard to the pulse duration, but it should be understood that the reduction reactant partial pressure is another means to control the reduction reactant dose. For spatial ALD, the reduction reactant exposure is controlled by the amount of time the substrate spends in the reduction reactant spatial domain and the reduction reactant partial pressure in the reduction reactant spatial domain. A carrier gas, such as argon or other non-reactive (with the substrate or the reduction reactant) gas, may be used.

The reduction reactant exposure may include exposing the substrate to the reduction reactant for an exposure time and a partial pressure of the reduction reactant so that the reduction reactant binds with a coating on the first area of the substrate, the second area of the substrate, or both. In some embodiments, given the brief time for the pulse/exposure for the ALD process the pulse lasts the entire exposure until the purge starts with the pulse time and exposure time being the same. The reduction reactant pulse time may be less than the exposure time, or they may be equal such that the exposure is the same as the pulse. The exposure time may be in the range of 0.5-500 seconds (e.g., 0.5, 1, 5, 10, 20, 30, 40, 50, 60, 70, 80, 90, 100, 120, 140, 160, 180, 200, 220, 240, 260, 280, 300, 350, 400, 450 or 500 seconds or several minutes, inclusive of all ranges and values therebetween). In some embodiments, the predetermined time is in the range of 1-10 seconds. The partial pressure of the reduction reactant may be in the range of 0.01-10 Torr (e.g., 0.01, 0.05, 0.1, 0.5, 1.0, 5.0, or 10 Torr, inclusive of all ranges and values therebetween). The partial pressure of the reduction reactant may be in the range of 0.1-1 Torr. ALD growth may also be performed at various reactor pressures (e.g., 10⁻⁴ Torr to 1000 Torr).

The reduction reactant purge evacuates unreacted reduction reactant from the reactor. The reduction reactant purge may be for a reduction reactant purge time of 0.5-30 seconds (e.g., 0.5, 1, 5, 10, 20, or 30 seconds, inclusive of all ranges and values therebetween), such as 15 seconds. The reduction reactant purge may evacuate the reactor such that the total pressure in the reactor is reduced substantially to vacuum. Alternatively, the reduction reactant purge may consist of a constant flow of high purity carrier gas at a constant pressure that sweeps the unreacted reduction reactant from the reactor. In either case, the reduction reactant purge reduces the partial pressure of the reduction reactant in the reactor by a factor of 10² to >10⁹ (e.g., from an initial value of 1 Torr immediately following the reduction reactant exposure to a final value after the reduction reactant purge of 10⁻² to <10⁻⁹ Torr).

The method may include the step, after step 130 or step 140, of contacting the substrate with a second co-reactant, the second co-reactant reactive with the first intermediate, forming a second thin film on the first area.

The substrate may be exposed to a second co-reactant. The second co-reactant may be reactive with the first precursor adsorbed on the substrate or reactive species (e.g., precursor complex) resulting from the first precursor's reaction with the substrate. The second co-reactant may be introduced into the reactor for a second co-reactant exposure time and at a partial pressure of the second co-reactant so that second co-reactant reacts with the surface sites formed by the first precursor reacting with the substrate (or previous ALD deposited coatings). The second co-reactant exposure time may be in the range of 0.5-500 seconds (e.g., 0.5, 1, 5, 10, 20, 30, 40, 50, 60, 70, 80, 90, 100, 120, 140, 160, 180, 200, 220, 240, 260, 280, 300, 350, 400, 450 or 500 seconds, inclusive of all ranges and values therebetween), such as about 1 second. The partial pressure of the second co-reactant may be in the range of 0.01-10 Torr (e.g., 0.01, 0.05, 0.1, 0.5, 1.0, 5.0, or 10 Torr, inclusive of all ranges and values therebetween). In some embodiments, the partial pressure of the second co-reactant is in the range of 0.1-1 Torr (e.g., about 0.5 Torr or 0.88 Torr). ALD growth may also be performed in various reactor pressures (10⁻⁴ Torr to 1000 Torr).

The second co-reactant purge may evacuate unreacted co-reactant from the reactor. The second co-reactant purge may be for a second co-reactant purge time of 0.5-500 seconds (0.5, 1, 5, 10, 20, 30, 40, 50, 60, 70, 80, 90, 100, 120, 140, 160, 180, 200, 220, 240, 260, 280, 300, 350, 400, 450 or 500 seconds, inclusive of all ranges and values therebetween), such as 10 seconds. The second co-reactant purge may evacuate the reactor such that the total pressure is reduced substantially to vacuum. Alternatively, the second co-reactant purge may consist of a constant flow of high purity carrier gas at a constant pressure that sweeps the unreacted co-reactant from the reactor. In either case, the second co-reactant purge may reduce the partial pressure of the co-reactant in the reactor by a factor of 10² to >10⁹ (e.g., from an initial value of 1 Torr immediately following the second co-reactant exposure to a final value after the second co-reactant purge of 10⁻² to <10⁻⁹ Torr).

The second co-reactant may be reactive only with the first intermediate and not reactive with the first thin film. In this case, this step may form the second thin film on the first area and not on the second area. Alternatively or additionally, the second co-reactant may be reaction with the first intermediate and the second intermediate, forming a second thin film on the first area and a third thin film on the second area.

The process 100 may include a cycle or multiple repeated cycles of steps 110-140, where cycles may be repeated to form desired film thicknesses. A cycle includes steps 110-140, and may further include additional steps as described herein, defining 1 dual ASD cycle. Dual ASD cycles may be repeated to deposit two uniform coatings, one on the first area of the substrate and the other on the second area of the substrate. The dual ASD process may be an ALD process. In some implementations, additional precursors and/or co-reactants may be sequentially introduced into the reactor as part of a supercycle. The ALD process may include a supercycle or multiple repeated supercycles. A supercycle combines ALD cycles for two or more ALD processes. For instance, a supercycle combining two ALD processes includes performing one or more ALD cycles for a first ALD process followed by one or more ALD cycles for a second ALD process. Supercycles may be used to form layered films, doped films, and/or gradient coating, as described above. Gradient coatings may be formed by varying the number of ALD cycles of each ALD process included in the supercycle as the coating is deposited.

It should be appreciated that more complicated ASD schemes can be constructed as super-cycles. Super-cycles may include various sub-cycles for depositing a material, for depositing multiple different materials, for multiple doped coatings, or for depositing bi-(tri-, etc.) metallic materials. The material deposited may vary based on the deposition parameters for any of the individual steps within a super-cycle. For example, the deposition may be a doped layer, a multi-layer, an alloy, a nanocomposite, or a mixed metal composite. The respective pulse and purge times may be the same time or may be different for the different metal precursors and co-reactants.

The combination of first precursor and second precursor may provide dual ASD as described herein. For example, the combination of first precursor and second precursor may be any of the combinations 1-7 in Table 1.

TABLE 1
Precursor Combinations

| | First Precursor | Second Precursor |
|---|---|---|
| 1 | Silicon precursor | Ruthenium precursor |
| 2 | Titanium precursor | Ruthenium precursor |
| 3 | Tungsten precursor | Ruthenium precursor |
| 4 | Silicon precursor | Hafnium precursor |
| 5 | Titanium precursor | Hafnium precursor |
| 6 | Tungsten precursor | Hafnium precursor |
| 7 | Silicon precursor | Aluminum precursor |

The first precursor for depositing coatings on the first area may include a silicon precursor, a titanium precursor, a tungsten precursor, or a combination thereof. Nonlimiting examples of the silicon precursor include bis(N,N-dimethylamino)dimethylsilane (DMADMS), N,N-dimethylamino)trimethylsilane (DMATMS), bis(tertbutylamino)silane (BTBAS), bis(diethylamino)silane (BDEAS), tris(dimethylamino)silane (TDMAS), or a combination of any two or more thereof. Nonlimiting examples of the titanium precursor include trimethoxy-(pentamethylcyclopentadienyl) titanium (IV) (TMPMCT). Nonlimiting examples of the tungsten precursor include ethylcyclopentadienyltungsten (V) tricarbonyl hydride (HEtCpW(CO)₃).

The second precursor for depositing coatings on the second area may include a ruthenium precursor, a hafnium precursor, an aluminum precursor, or a combination of any two or more thereof. Nonlimiting examples of the ruthenium precursor include dicarbonyl-bis(5-methyl-2,4-hexanediketonato)ruthenium (II), bis(ethylcyclopentadienyl)ruthenium (II) (Ru(EtCp)₂), and tricarbonyl (η4-2-methylene-1,3-propanediyl)ruthenium (II) (TRUST). Nonlimiting examples of the hafnium precursor include tetrakis (dimethylamino) hafnium (TDMAH). Nonlimiting examples of the hafnium precursor include dimethylaluminum isopropoxide (DMAI).

The first co-reactant for depositing coatings on the second area may include oxygen constituents, for example, water (H₂O), oxygen (O₂), oxygen plasma, ozone (O₃), hydrogen peroxide (H₂O₂), nitrous oxide (N₂O), formaldehyde (CH₂O), or any combination of two or more thereof.

The second co-reactant for depositing coatings on the first area may include oxygen constituents, for example, water (H₂O), oxygen (O₂), oxygen plasma, ozone (O₃), hydrogen peroxide (H₂O₂), nitrous oxide (N₂O), formaldehyde (CH₂O), or any combination of two or more thereof. The second co-reactant for depositing metallic coatings may include a reduction reactant. Nonlimiting examples of the reduction reactant include hydrogen gas, hydrogen plasma, a mixture of hydrogen gas plasma and a non-reactive gas plasma (e.g., argon, “Ar/H₂”), ammonia, hydrazine, or a combination of any two or more.

The reduction reactant for reducing the first thin film, the second thin film, or the combination thereof, where the thin film is an on oxide, may include hydrogen gas, hydrogen plasma, a mixture of hydrogen gas plasma and a non-reactive gas plasma (e.g., argon, “Ar/H₂”), ammonia, hydrazine, or a combination of any two or more.

For example, the combination of first precursor, second precursor, first co-reactant, and second co-reactant may be any of the combinations 1-11 in Table 2.

Any of the intermediates formed by contacting precursors with the substrate may be adsorbates. The adsorbate may be formed by chemisorption or physisorption of the precursor with the substrate. The intermediate may be a complex formed on the surface of the substrate.

TABLE 2
Precursor and Co-Reactant Combinations

| | First Precursor | Second Precursor | First Co-Reactant | Second Co-Reactant |
|---|---|---|---|---|
| 1 | Bis(N,N-dimethylamino)dimethylsilane | Dicarbonyl-bis(5-methyl-2,4- | H₂O, O₂, or a | O₂ plasma, O₃, or a |
| | (DMADMS), N,N- | hexanediketonato)ruthenium (II) | combination thereof | combination thereof |
| | dimethylamino)trimethylsilane | | | |
| | (DMATMS), | | | |
| | bis(tertbutylamino)silane (BTBAS), | | | |
| | bis(diethylamino)silane (BDEAS), | | | |
| | tris(dimethylamino)silane (TDMAS), or a | | | |
| | combination of any two or more thereof | | | |
| 2 | Trimethoxy- | Dicarbonyl-bis(5-methyl-2,4- | H₂O, O₂ or a | O₂, O₂ plasma, O₃, or |
| | (pentamethylcyclopentadienyl) titanium | hexanediketonato)ruthenium (II) | combination thereof | a combination of any |
| | (IV) (TMPMCT) | | | two or more thereof |
| 3 | Ethylcyclopentadienyltungsten (V) | Dicarbonyl-bis(5-methyl-2,4- | H₂O, O₂, or a | Ar/H₂ plasma |
| | tricarbonyl hydride (HEtCpW(CO)₃) | hexanediketonato)ruthenium (II) | combination thereof | |
| 4 | Bis(N,N-dimethylamino)dimethylsilane | Bis(ethylcyclopentadienyl)ruthenium (II) | O₂ | O₂ plasma, O₃, or a |
| | (DMADMS), N,N- | (Ru(EtCp)₂) | | combination thereof |
| | dimethylamino)trimethylsilane | | | |
| | (DMATMS), | | | |
| | bis(tertbutylamino)silane (BTBAS), | | | |
| | bis(diethylamino)silane (BDEAS), | | | |
| | tris(dimethylamino)silane (TDMAS), or a | | | |
| | combination of any two or more thereof | | | |
| 5 | Ethylcyclopentadienyltungsten (V) | Bis(ethylcyclopentadienyl)ruthenium (II) | O₂ | Ar/H₂ plasma |
| | tricarbonyl hydride (HEtCpW(CO)₃) | (Ru(EtCp)₂) | | |
| 6 | Bis(N,N-dimethylamino)dimethylsilane | Tricarbonyl (η4-2-methylene-1,3- | H₂O, O₂, or a | O₂ plasma, O₃, or a |
| | (DMADMS), N,N- | propanediyl)ruthenium(II) (TRuST) | combination thereof | combination thereof |
| | dimethylamino)trimethylsilane | | | |
| | (DMATMS), | | | |
| | bis(tertbutylamino)silane (BTBAS), | | | |
| | bis(diethylamino)silane (BDEAS), | | | |
| | tris(dimethylamino)silane (TDMAS), or a | | | |
| | combination of any two or more thereof | | | |
| 7 | Ethylcyclopentadienyltungsten (V) | Tricarbonyl (η4-2-methylene-1,3- | H₂O, O₂, or a | Ar/H₂ plasma |
| | tricarbonyl hydride (HEtCpW(CO)₃) | propanediyl)ruthenium(II) (TRuST) | combination thereof | |
| 8 | Bis(N,N-dimethylamino)dimethylsilane | Tetrakis(dimethylamino) hafnium | H₂O, O₂, O₃, or a | O₂ plasma, O₃, or a |
| | (DMADMS), N,N- | (TDMAH) | combination of any | combination thereof |
| | dimethylamino)trimethylsilane | | two or more thereof | |
| | (DMATMS), | | | |
| | bis(tertbutylamino)silane (BTBAS), | | | |
| | bis(diethylamino)silane (BDEAS), | | | |
| | tris(dimethylamino)silane (TDMAS), or a | | | |
| | combination of any two or more thereof | | | |
| 9 | Trimethoxy- | Tetrakis(dimethylamino) hafnium | H₂O, O₂, O₃, or a | O₂, O₂ plasma, O₃, or |
| | (pentamethylcyclopentadienyl) titanium | (TDMAH) | combination of any | a combination of any |
| | (IV) (TMPMCT) | | two or more thereof | two or more thereof |
| 10 | Ethylcyclopentadienyltungsten (V) | Tetrakis(dimethylamino) hafnium | H₂O, O₂, O₃, or a | Ar/H₂ plasma |
| | tricarbonyl hydride (HEtCpW(CO)₃) | (TDMAH) | combination of any | |
| | | | two or more thereof | |
| 11 | Bis(N,N-dimethylamino)dimethylsilane | dimethylaluminum isopropoxide (DMAI) | H₂O | O₃ |
| | (DMADMS), N,N- | | | |
| | dimethylamino)trimethylsilane | | | |
| | (DMATMS), | | | |
| | bis(tertbutylamino)silane (BTBAS), | | | |
| | bis(diethylamino)silane (BDEAS), | | | |
| | tris(dimethylamino)silane (TDMAS), or a | | | |
| | combination of any two or more thereof | | | |

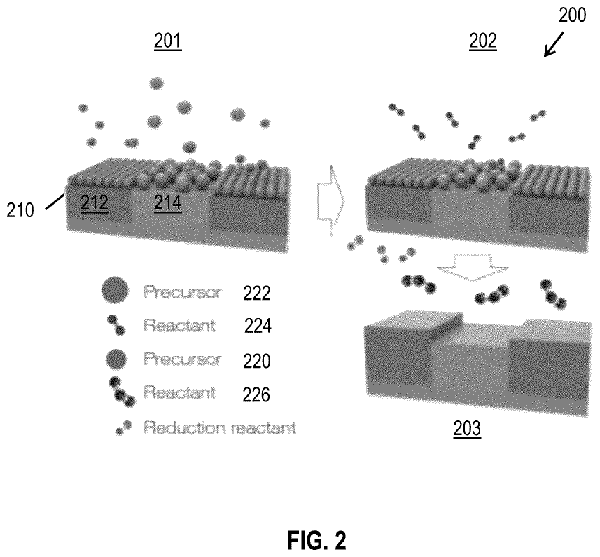

FIG. 2 is an illustration of another process 200 of dual ASD. In step 201, a substrate 210 having a first section 212 terminated with hydroxyl groups and a second section 214 terminated with hydrogen groups or metallic groups is sequentially contact with a first precursor 220, which forms an intermediate with the first section 212, and a second precursor 222, which forms an intermediate with the second section 214. In step 202, the substrate is contacted with a first co-reactant 224, which forms a first thin film on the second section 214. In step 203, the substrate is contacted with a second co-reactant 226, which forms a second thin film on the first section 212. In some embodiments, the second co-reactant 226 may also etch the first thin film on the second section 214. The precursors, co-reactants, dosing regimens, and other characteristics of the process 200 may be consistent with any of those described with respect to FIG. 1.

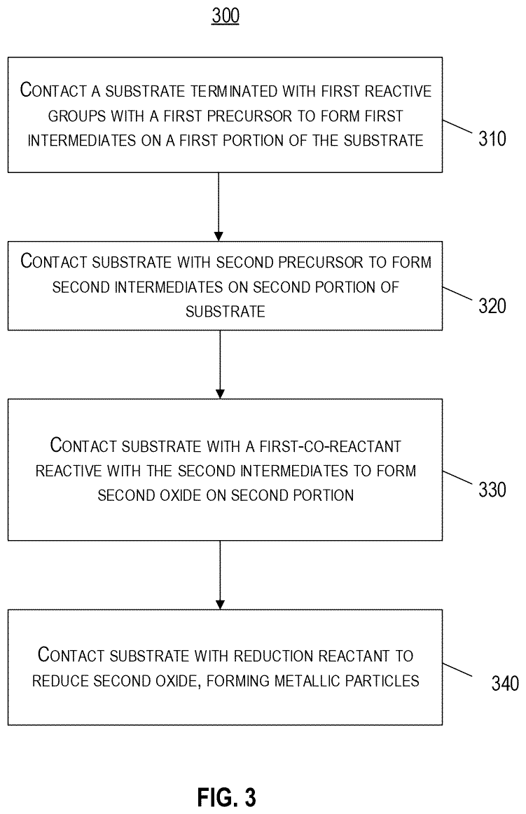

In another aspect, a method of forming particles is disclosed. FIG. 3 is a flow diagram of a process 300 of using dual ASD to form particles. The process takes advantage of the first precursor acting as an inhibitor and presenting steric hindrance, leaving some sites on the surface of the substrate unoccupied, such that when the second precursor is exposed to the surface it only forms intermediates at these unoccupied sites. The adsorption density of the second precursor on the surface is lower than in a typical metal ALD process.

The process 300 includes step 310 of contacting a substrate terminated with a plurality of first reactive groups (e.g., hydroxyl groups) with a first precursor to form a plurality of first intermediates on a first portion of the substrate. The dose of the first precursor, and the arrangement of first reactive groups on the substrate surface may be varied to change the size and density of the particles formed.

The process 300 includes step 320 of contacting the substrate with a second precursor to form a plurality of second intermediates on a second portion of the substrate. The second portion may be different from the first portion, and the second precursor may include a metal. The second portion may be areas of the substrate where steric hindrance prevents formation of first intermediates.

The process 300 includes step 330 of contacting the substrate with a first co-reactant reactive with the plurality of second intermediates to form a second oxide on the second portion. The second oxide may include a metal oxide. The process 300 includes step 340 of contacting the substrate with hydrogen gas to reduce the second oxide, forming a plurality of metallic particles on the second portion of the substrate.

In some embodiments, the first co-reactant in step 330 may be reactive with the plurality of first intermediates, and step 330 may include reacting the first co-reactant with the plurality of first intermediates to form a first oxide on the first portion. In these embodiments, the process 300 may include, after step 340, contacting the substrate with the first precursor to form a plurality of third intermediates on the first oxide; contacting the substrate with the second precursor to form a plurality of fourth intermediates on the plurality of metallic particles; contacting the substrate with the first co-reactant reactive with the plurality of third intermediates to form a third oxide on the first oxide and reactive with the plurality of fourth intermediates to form a fourth oxide on the plurality of metallic particles; the fourth oxide comprising a metal oxide; and contacting the substrate with reduction reactant to reduce the fourth oxide to metal, increasing a dimension of the plurality of metallic particles on the second portion of the substrate. These steps may be repeated a plurality of times to increase the dimension of the plurality of metallic particles and increase the thickness of the first oxide. The first precursor may include a silicon precursor; the second precursor may include a ruthenium precursor, a hafnium precursor, or an aluminum precursor; the first co-reactant may include ozone; and the second co-reactant may include ozone.

In some embodiments, the first co-reactant in step 330 may not be reactive with the plurality of first intermediates or only partially reactive with the first intermediates, and step 330 may not include reacting the first co-reactant with the plurality first intermediates or may include only partial reaction of the first co-reactant with the plurality first intermediates. In these embodiments, the process 300 may include, after step 340, contacting the substrate with the second precursor to form a plurality of fourth intermediates on the plurality of metallic particles; contacting the substrate with the first co-reactant reactive with the plurality of fourth intermediates to form a third oxide on the plurality of metallic particles; the third oxide comprising a metal oxide; and contacting the substrate with reduction reactant to reduce the third oxide to metal, increasing a dimension of the plurality of metallic particles on the second portion of the substrate. The method may include repeating these steps a plurality of times to increase the dimension of the plurality of metallic particles without increasing the thickness of the first oxide, or limiting the increase in the thickness of the first oxide. The method may further include contacting the substrate with a second co-reactant reactive with the plurality of first intermediates to form a fourth oxide on the first portion of the substrate. The first precursor may include a silicon precursor; the second precursor may include a ruthenium precursor, a hafnium precursor, or an aluminum precursor; the first co-reactant may include oxygen; the second co-reactant may include O₃, and the reduction reductant may include hydrogen.

The process 300 may include a cycle or multiple repeated cycles of any of these steps, where cycles may be repeated to form desired film thicknesses. A cycle may include steps 310-340, and may further include additional steps as described herein, defining 1 dual ASD cycle. Dual ASD cycles may be repeated to deposit two uniform coatings, one on the first area of the substrate and the other on the second area of the substrate. The dual ASD process may be an ALD process, and 1 dual ASD cycle may be 1 ALD cycle. In some implementations, additional precursors and/or co-reactants may be sequentially introduced into the reactor as part of a supercycle. The ALD process may include a supercycle or multiple repeated supercycles. A supercycle combines ALD cycles for two or more ALD processes. For instance, a supercycle combining two ALD processes includes performing one or more ALD cycles for a first ALD process followed by one or more ALD cycles for a second ALD process. Supercycles may be used to form layered particles, doped particles, and/or gradient particles, as described above. Gradient particles may be formed by varying the number of ALD cycles of each ALD process included in the supercycle as the particles are deposited.

For example, the process 300 may further include contacting the substrate with the first precursor to form a plurality of third intermediates on the first oxide. The process 300 may further include contacting the substrate with the second precursor to form a plurality of fourth intermediates on the second oxide. The process 300 may further include contacting the substrate with a second co-reactant reactive with the plurality of fourth intermediates to form a third oxide on the second oxide. The third oxide may include a metal oxide. The process 300 may further include contacting the substrate with hydrogen gas to reduce the third oxide, increasing a dimension of the plurality of metallic particles on the second portion of the substrate. These steps may be repeated a plurality of times to increase the dimension of the plurality of metallic particles.

The precursors, co-reactants, dosing regimens, and other characteristics of the process 300 of FIG. 3 may be consistent with any of those described with respect to FIG. 1.

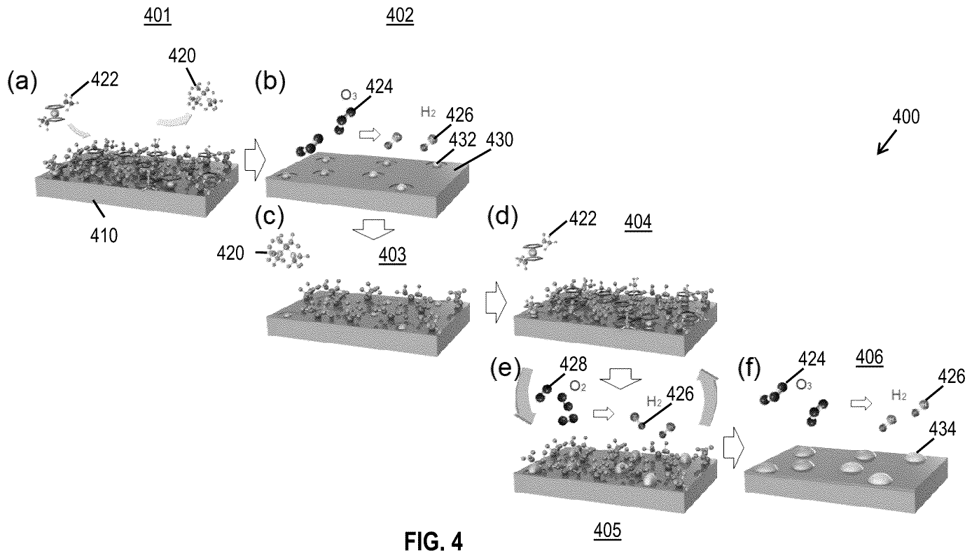

FIG. 4 is an illustration of another process 400 of forming metallic nanoparticles. In step 401, the substrate 410 is contacted with the first precursor 420 (e.g., DMADMS), forming first regions of first precursor intermediates on the surface, and the substrate 410 is contacted with the second precursor 422 (e.g., Ru(EtCp)₂), forming second regions of second precursor intermediates on the surface at sites not occupied by first precursor intermediates (e.g., due to steric hindrance between first precursor molecules). In step 402, the substrate is contacted with co-reactant 424 (e.g., O₃), which reacts with the first precursor intermediates and the second precursor intermediates, forming oxides 430 and 432, where oxides 432 may be a thin film or a plurality of particles interspersed between regions of thin film oxide 430. The substrate is then contacted with reduction reactant 426 (e.g., H₂) to reduce oxides 432 to metal. In step 403, the substrate may be contacted with the first precursor 420 again, forming first precursor intermediates on the first region oxide 430. In step 404, the substrate may be contacted with the second precursor 422 again, forming second precursor intermediates on the metal. In step 405, the substrate is contacted with co-reactant 428, which does not react with the first precursor intermediates but reacts with the second precursor intermediates to form oxide 432. The substrate is then contacted with reduction reactant 426 again to reduce oxide 432 to the metal, thereby increasing a dimension (e.g., diameter) of the metallic particles. Steps 404 and 405 may be repeated a number of times to increase the dimension of the metallic particles to a predetermined dimension without concurrently growing the thickness of the metal oxide film 430. In step 406, the substrate is contacted with the co-reactant 424 and the reduction reactant 426 to react any remaining precursor intermediates or metal oxides.

The precursors, co-reactants, dosing regimens, and other characteristics of the process 400 of FIG. 4 may be consistent with any of those described with respect to FIG. 1.

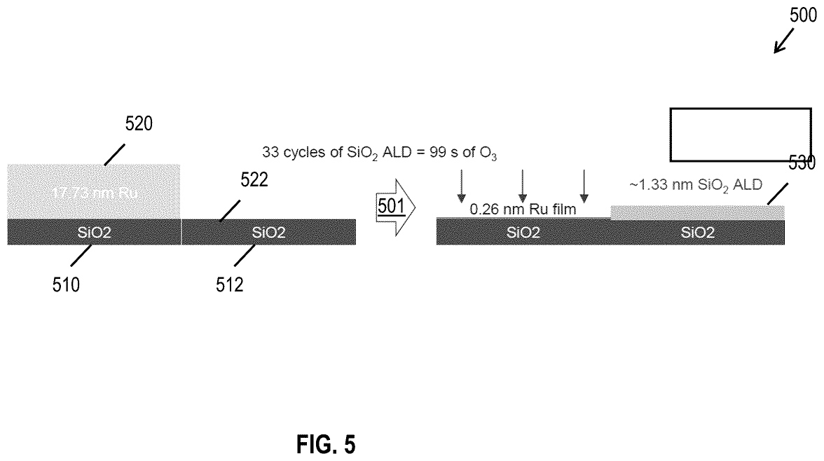

In another aspect, the method of dual ASD may include area-selective etching (ASE). FIG. 5 is an illustration of a process 500 of etching a metal film (e.g., ruthenium) 520 that was deposited on second area 510 but not on first area 512 according to the process 100 of FIG. 1, such that the first area 512 of the substrate surface is oxide 522. In step 501, the substrate, including metal film 520 and oxide 522 (e.g., silicon dioxide), are exposed to O₃ at a temperature in the range of 100 °C-350 °C (e.g., 100, 110, 120, 130, 140, 150, 160, 170, 180, 190, . . . 350 °C, inclusive of all ranges and values therebetween) to etch the metal film 520 but not etch the oxide 522. The ASE may form additional oxide on the oxide 522.

Typically, the ASE process takes place in a uniform temperature-controlled reactor. In some embodiments, the substrate may be heated to a predetermined temperature during the ALD process. For example, the first predetermined temperature may be in the range of 100 °C-350 °C (e.g., 100, 110, 120, 130, 140, 150, 160, 170, 180, 190, . . . 350 °C, inclusive of all ranges and values therebetween). In some embodiments, the predetermined temperature is in the range of 200-300 °C (e.g., 240 °C).

The size of the O₃ dose or number of doses may be varied to change the amount metal etching. The O₃ may be introduced into the reactor for an exposure time and at a partial pressure so that O₃ reacts with the metal. The O₃ exposure time may be in the range of 0.5-500 seconds (e.g., 0.5, 1, 5, 10, 20, 30, 40, 50, 60, 70, 80, 90, 100, 120, 140, 160, 180, 200, 220, 240, 260, 280, 300, 350, 400, 450 or 500 seconds, inclusive of all ranges and values therebetween), such as about 1 second. The partial pressure of the O₃ may be in the range of 0.01-10 Torr (e.g., 0.01, 0.05, 0.1, 0.5, 1.0, 5.0, or 10 Torr, inclusive of all ranges and values therebetween). In some embodiments, the partial pressure of the O₃ is in the range of 0.1-1 Torr (e.g., about 0.5 Torr or 0.88 Torr). ASE may also be performed in various reactor pressures (10⁻⁴ Torr to 1000 Torr). The O₃ dose may include a mixture of 03 and O₂ (e.g., about 5% to about 30%, about 5%, about 10%, about 20%, or about 30% O₃ in O₂).

The O₃ purge may evacuate unreacted co-reactant from the reactor. The O₃ purge may be for a purge time of 0.5-500 seconds (0.5, 1, 5, 10, 20, 30, 40, 50, 60, 70, 80, 90, 100, 120, 140, 160, 180, 200, 220, 240, 260, 280, 300, 350, 400, 450 or 500 seconds, inclusive of all ranges and values therebetween), such as 10 seconds. The purge may evacuate the reactor such that the total pressure is reduced substantially to vacuum. Alternatively, the purge may consist of a constant flow of high purity carrier gas at a constant pressure that sweeps the unreacted O₃ from the reactor. In either case, the O₃ purge may reduce the partial pressure of the O₃ in the reactor by a factor of 10² to >10⁹ (e.g., from an initial value of 1 Torr immediately following the O₃ exposure to a final value after the purge of 10⁻² to <10⁻⁹ Torr).

The number of O₃ doses may depend on the desired amount of etching and the thickness of the metal film. Each O₃ dose may include an O₃ purge. The number of O₃ doses may be in the range of 1-500 (e.g., 1, 5, 10, 20, 30, 40, 50, 60, 70, 80, 90, 100, 120, 140, 160, 180, 200, 220, 240, 260, 280, 300, 350, 400, 450 or 500 doses, inclusive of all ranges and values therebetween), such as about 10 doses.

For example, a 99 second dose of 03 at 240 °C may etch 17.47 nm of Ru film in the second area, and deposit about 1.33 nm of SiO₂ on the first area, where the first area oxide 522 is silicon dioxide.

The present invention, thus generally described, will be understood more readily by reference to the following examples, which are provided by way of illustration and are not intended to be limiting of the present invention.

### EXAMPLES

### Example 1: Ruthenium Deposition

Ruthenium deposition used the metal precursor (η4-2-methylene-1,3-propanediyl)ruthenium (II) (TRUST), the co-reactant O₂, and the reduction reactant H₂. The reduction reactant was a mixture of H₂ in argon gas (H₂/Ar). A cycle was defined as the sequence: dose of the metal precursor (3 seconds(s) of TRUST), reactor purge (15 s of N₂), dose of the co-reactant (3 s of O₂), reactor purge (15 s of N₂), dose of reduction reactant (5 s of H₂), and reactor purge (15 s of N₂). Deposition was conducted in an atomic layer deposition (ALD) reactor at a temperature of 240 °C, unless otherwise noted.

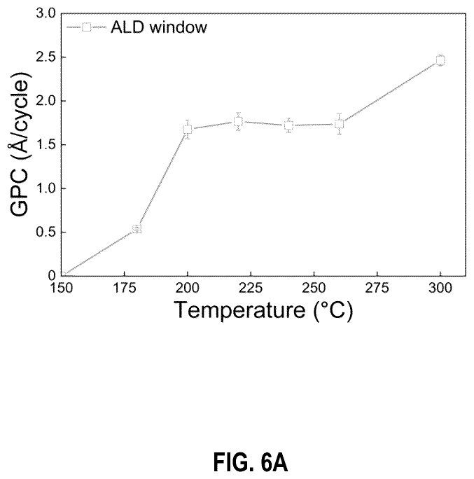

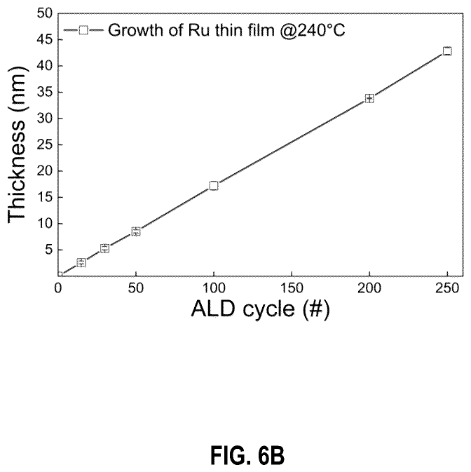

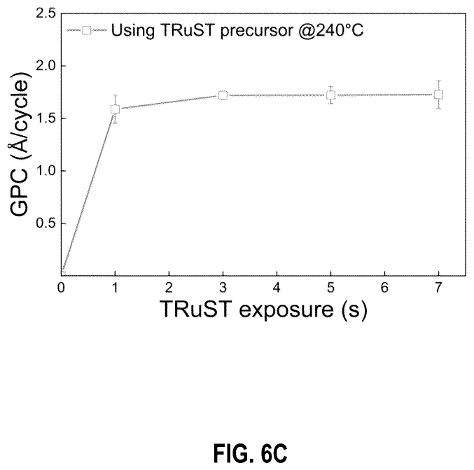

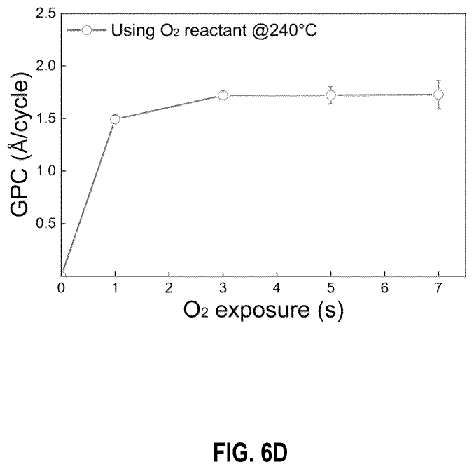

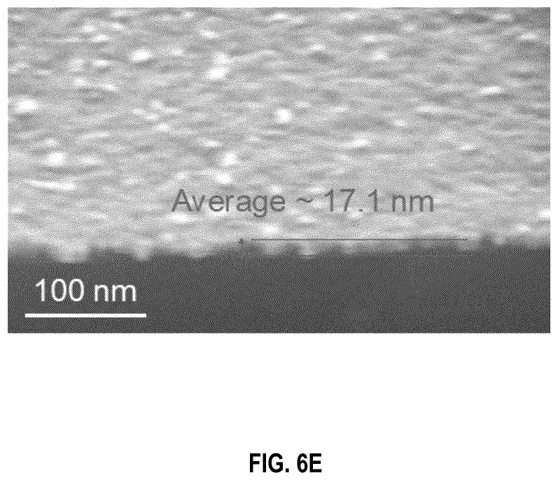

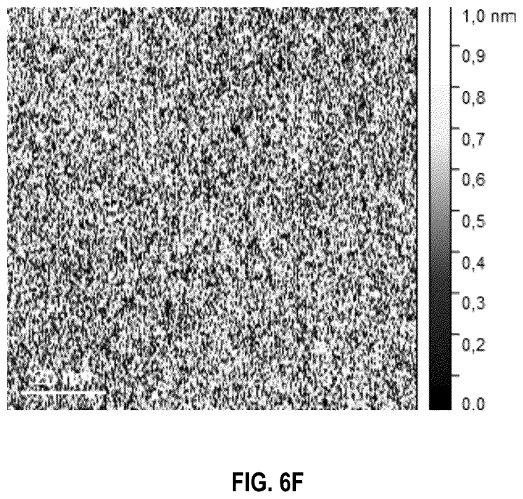

FIGS. 6A-6F provide characterization of ruthenium deposition. FIG. 6A is a graph of growth per cycle (GPC) of ruthenium at different temperatures as determined using spectroscopic ellipsometry (GPC=thickness after 100 Ru ALD deposition cycles/100). Results in FIG. 6A indicate a window between 200 °C and 260 °C at which the GPC is about 1.7 Å/cycle, indicating an ALD window of self-limiting growth. Temperatures lower than 200 °C provided lower GPC. Without being bound by any theory, the lower growth rate may result from the metal precursor not dosing at a high enough amount to saturate surface sites due to the metal precursor vapor pressure at the lower temperature. Temperatures higher than 260 °C provided higher GPC. Without being bound by any theory, the higher growth rate may be related to decomposition of the metal precursor.

FIG. 6B is a graph of deposited ruthenium thickness with number of deposition cycles. The number of cycles varied between 10 cycles and 300 cycles, and the growth rate of ruthenium deposition was linear over all cycles at about 1.71 Å/cycle.

FIG. 6C is a graph of GPC of the ruthenium film with length of ruthenium precursor dose. The characterization of GPC with increasing length of ruthenium precursor dose may indicate self-limiting growth of the ruthenium film, which may indicate ALD deposition. Over 1-7 seconds of exposure of the ruthenium metal precursor, the growth per cycle remained at about 1.71 Å/cycle.

FIG. 6D is a graph of GPC of ruthenium with length of oxygen exposures. The characterization of GPC with increasing length of co-reactant precursor dose may indicate self-limiting growth of the ruthenium film, which may indicate ALD deposition. Over 3-7 seconds of co-reactant exposure, the GPC remained at about 1.71 Å/cycle, with 1 second exposure providing a slightly lower GPC of about 1.5 Å/cycle.

FIG. 6E is a cross-sectional image of the ruthenium film acquired with scanning electron microscopy (SEM). The ruthenium film was deposited on silicon with a native oxide with 100 cycles of deposition. SEM indicated a uniform thickness of about 17.1 nm of ruthenium on the substrate.

FIG. 6F is atomic force microscopy (AFM) characterization of the roughness of the ruthenium film. The ruthenium film was deposited on silicon with a native oxide with 100 cycles of deposition. AFM indicated a root mean square roughness (RRMS) of 0.248±0.013 nm.

### Example 2: Area Selective Deposition Using an Inhibitor

Dual area selective deposition (ASD) of ruthenium and silicon dioxide in accordance with the process of FIG. 2. A silicon substrate having a first area terminated with silica having hydroxyl groups on the surface and a second area terminated with H—Si. Deposition was conducted in an atomic layer deposition (ALD) reactor held at 240 °C with a carrier gas flow of 200 sccm. A cycle was defined as the sequence: dose of silicon precursor (10 seconds of DMADMS), reactor purge (30 seconds of N₂), dose of the metal precursor (3 seconds of TRUST), reactor purge (15 seconds of N₂), dose of the first co-reactant (3 seconds of 02), reactor purge (15 seconds of N₂), dose of second co-reactant (3 seconds of 03), dose of reduction reactant (5 seconds of Ar/H₂), reactor purge (15 seconds of N₂). The silicon precursor was used as the inhibitor to block growth of ruthenium on the first area terminated with hydroxyl groups by exploiting that the silicon precursor adsorbs on hydroxyl-terminated surfaces but not on H—Si or metal surfaces. The silicon precursor was bis(N,N-dimethylamino)dimethylsilane (DMADMS). The metal precursor was TRUST. The first co-reactant was O₂ and the second co-reactant was ozone. The reduction reactant was Ar/H₂.

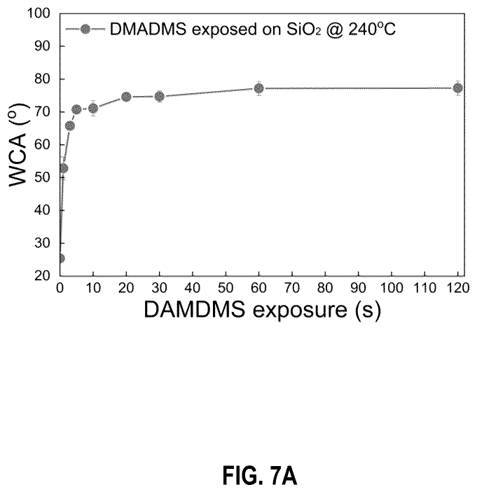

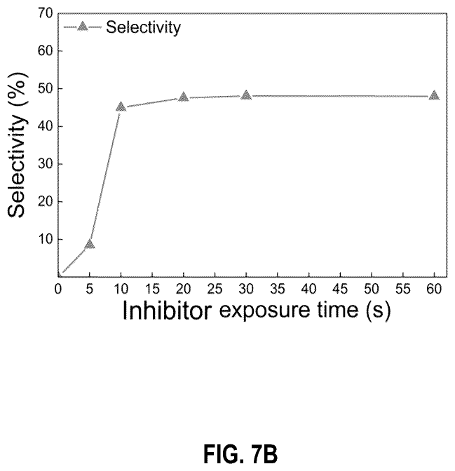

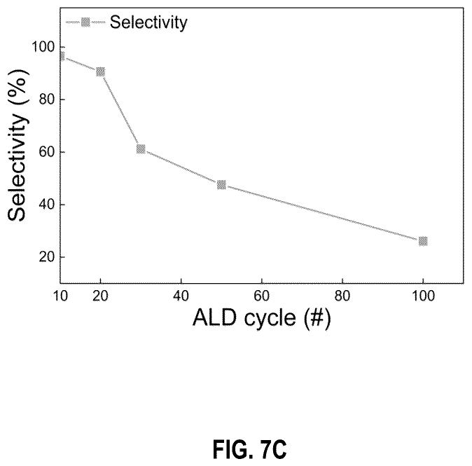

FIGS. 7A-7C provide characterization of ruthenium area selective deposition (ASD). FIG. 7A is a graph of water contact angle (WCA) on a silicon substrate with duration of exposures of bis(N,N-dimethylamino)dimethylsilane (DMADMS). WCA of bare SiO₂ was 25.4°. Upon increasing duration of exposure of DMADMS, the WCA of the surface increased until reaching a threshold of about 20 seconds of DMADMS exposure (about 0.03 Torr), where the WCA was about 75°, indicating self-limiting behavior.

FIG. 7B is a graph of selectivity with length of exposures of DMADMS. Selectivity was defined as: (t₁−t₂)/(t₁+t₂). 100% where t₁ is the Ru thickness on the growth surface (e.g., Si—H), which is not covered by the inhibitor DMADMS, and t₂ is the Ru thickness on the non-growth surface (e.g., Si—OH), which is covered by the inhibitor DMADMS. Exposure time of DMADMS varied between 5 seconds and 60 seconds. Selectivity reached a threshold of about 47% at 10 seconds of DMADMS exposure time. The number of deposition cycles was maintained constant at 50 cycles.

FIG. 7C is a graph of selectivity with number of deposition cycles. Cycles of dual area-selective deposition varied between 10 and 100 cycles. Selectivity was about 99% at 10 cycles and decreased with increasing number of cycles.

### Example 3: Silica Deposition

Silicon oxide was deposited on 500 nm of silicon dioxide. SiO₂ was deposited using DMADMS as the precursor and O₃ as the co-reactant. Deposition was conducted in an atomic layer deposition (ALD) reactor held at 240 °C. A cycle was defined as the sequence: dose DMADMS, reactor purge, dose O₃, reactor purge. The DMADMS dose was 10 seconds and the O₃ dose was 3 seconds.

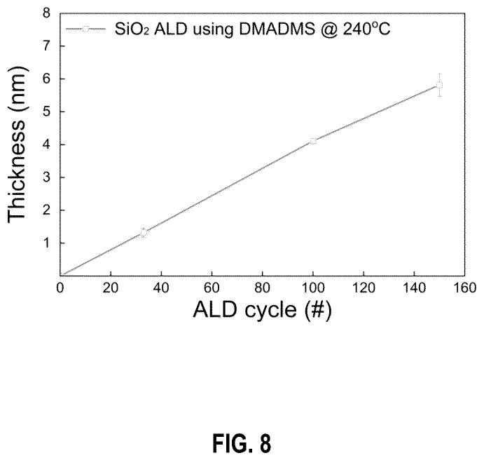

FIG. 8 is a graph of silicon oxide thickness with number of silicon oxide deposition cycles. Thickness was measured with spectroscopic ellipsometry.

### Example 4: Selective Etching of Ruthenium

Ruthenium etching was performed in accordance with the process in FIG. 5. Ruthenium was etched by contacting the ruthenium surface with O₃ in an atomic layer deposition (ALD) reactor held at a temperature of about 100 °C to about 300 °C. The initial thickness of the ruthenium film on the SiO₂ substrate was about 17.73 nm.

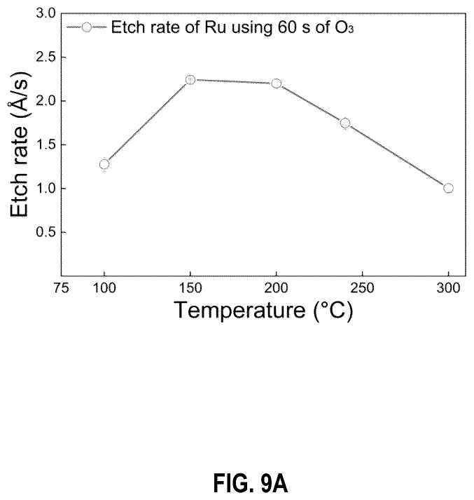

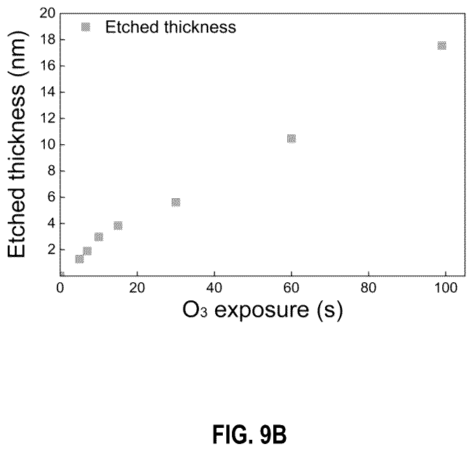

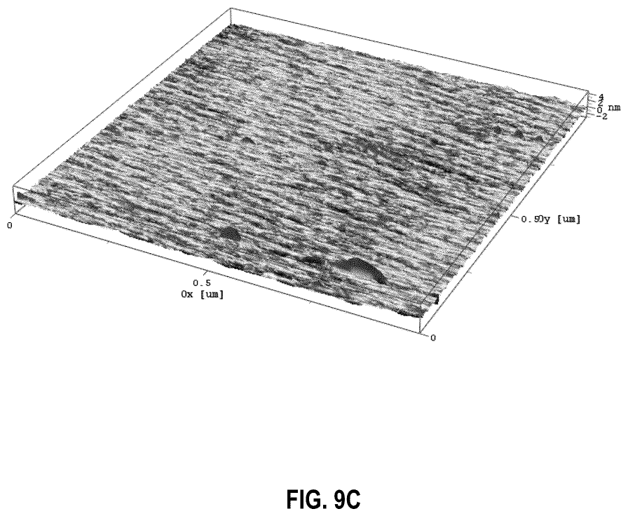

FIGS. 9A-9C provide characterization of ruthenium etching by ozone. FIG. 9A is a graph of etch rate at a temperature of about 100 °C to about 300 °C using 60 seconds of 03. The etch rate was higher at temperatures of 150 °C to 200 °C and decreased at higher temperatures. Without being bound by any theory, this may be due to the formation of RuO₂ and RuO₄ at these temperatures.

FIG. 9B is a graph of etched thickness with length of ozone exposure (0.88 Torr) at 240 °C. The thickness of ruthenium etched increased with increasing length of O₃ exposure between 2 seconds and 99 seconds. 99 seconds of O₃ exposure provided 17.47 nm of ruthenium etched.

FIG. 9C provides AFM characterization of the roughness of the etched ruthenium surface after 99 seconds of O₃ exposure. AFM results indicated a RRMS of 0.893±0.004 nm.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions, or biological systems, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

What is claimed is:

1. A method of area selective deposition comprising:
(A) providing a substrate comprising a first area terminated with a first reactive group and a second area terminated with a second reactive group;
(B) contacting the substrate with a first precursor reactive with the first reactive group to form a first intermediate on the first area;
(C) contacting the substrate with a second precursor reactive with the second reactive group to form a second intermediate on the second area; and
(D) contacting the substrate with a first co-reactant, the first co-reactant reactive with the second intermediate, forming a first thin film on the second area.

2. The method of claim 1, further comprising contacting the substrate with a reduction reactant, the reduction reactant reactive with the first thin film to reduce the first thin film.

3. The method of claim 2, further comprising (E) contacting the substrate with a second co-reactant, the second co-reactant reactive with the first intermediate, forming a second thin film on the first area.

4. The method of claim 3, wherein the first precursor comprises a silicon precursor; the second precursor comprises a ruthenium precursor, a hafnium precursor, an aluminum precursor, or a combination thereof; the first co-reactant comprises water, oxygen, or a combination thereof; and the second co-reactant comprises oxygen plasma, ozone, or a combination thereof.

5. The method of claim 4, wherein the silicon precursor comprises bis(N,N-dimethylamino)dimethylsilane (DMADMS), N,N-dimethylamino)trimethylsilane (DMATMS), bis(tertbutylamino)silane (BTBAS), bis(diethylamino)silane (BDEAS), tris(dimethylamino)silane (TDMAS), or a combination of any two or more thereof.

6. The method of claim 4, wherein the second precursor comprises the ruthenium precursor and the ruthenium precursor comprises dicarbonyl-bis(5-methyl-2,4-hexanediketonato)ruthenium (II), bis(ethylcyclopentadienyl)ruthenium (II), tricarbonyl (η4-2-methylene-1,3-propanediyl)ruthenium (II), or a combination of any two or more thereof.

7. The method of claim 4, wherein the second precursor comprises the hafnium precursor, and the hafnium precursor comprising tetrakis(dimethylamino) hafnium (TDMAH).

8. The method of claim 4, wherein the second precursor comprises the aluminum precursor, and the aluminum precursor comprising dimethylaluminum isopropoxide (DMAI).

9. The method of claim 3, wherein the first precursor comprises a tungsten precursor, the second precursor comprises a ruthenium precursor, a hafnium precursor, or a combination thereof; the first co-reactant comprises water, oxygen, or a combination thereof, and the second co-reactant comprises Ar/H₂ plasma.

10. The method of claim 3, wherein the first precursor comprises a titanium precursor; the second precursor comprises a ruthenium precursor, a hafnium precursor, or a combination thereof; the first co-reactant comprises water, oxygen, or a combination thereof; and the second co-reactant comprises oxygen plasma, ozone, or a combination thereof.

11. The method of claim 1, further comprising (F) contacting the substrate with a second co-reactant, the second co-reactant reactive with the first intermediate, forming a second thin film on the first area.

12. The method of claim 11, wherein the first precursor comprises a titanium precursor; the second precursor comprises a ruthenium precursor, a hafnium precursor, or a combination thereof; the first co-reactant comprises water, oxygen, or a combination thereof; and the second co-reactant comprises oxygen plasma, ozone, or a combination thereof.

13. The method of claim 11, further comprising contacting the first thin film and the second thin film with O₃ to etch the first thin film.

14. A method of forming particles comprising:
(A) contacting a substrate terminated with a plurality of first reactive groups with a first precursor to form a plurality of first intermediates on a first portion of the substrate;
(B) contacting the substrate with a second precursor to form a plurality of second intermediates on a second portion of the substrate, the second portion different from the first portion, and the second precursor comprising a metal;
(C) contacting the substrate with a first co-reactant reactive with the plurality of second intermediates to form a second oxide on the second portion, the second oxide comprising a metal oxide; and
(D) contacting the substrate with reduction reactant to reduce the second oxide to metal, forming a plurality of metallic particles on the second portion of the substrate.

15. The method of claim 14, wherein step (C) further comprises the first co-reactant reactive with the plurality of first intermediates to form a first oxide on the first portion; and the method further comprises:
(E) contacting the substrate with the first precursor to form a plurality of third intermediates on the first oxide;
(F) contacting the substrate with the second precursor to form a plurality of fourth intermediates on the plurality of metallic particles;
(G) contacting the substrate with the first co-reactant reactive with the plurality of third intermediates to form a third oxide on the first oxide and reactive with the plurality of fourth intermediates to form a fourth oxide on the plurality of metallic particles; the fourth oxide comprising a metal oxide; and
(H) contacting the substrate with reduction reactant to reduce the fourth oxide to metal, increasing a dimension of the plurality of metallic particles on the second portion of the substrate.

16. The method of claim 15, further comprising repeating steps (E) to (H) a plurality of times to increase the dimension of the plurality of metallic particles.

17. The method of claim 15, wherein the first precursor comprises a silicon precursor; the second precursor comprises a ruthenium precursor, a hafnium precursor, or an aluminum precursor; and the first co-reactant comprises ozone.

18. The method of claim 14, further comprising: (E) contacting the substrate with the second precursor to form a plurality of fourth intermediates on the plurality of metallic particles;
(F) contacting the substrate with the first co-reactant reactive with the plurality of fourth intermediates to form a third oxide on the plurality of metallic particles; the third oxide comprising a metal oxide; and
(G) contacting the substrate with reduction reactant to reduce the third oxide to metal, increasing a dimension of the plurality of metallic particles on the second portion of the substrate.

19. The method of claim 18, further comprising: (H) contacting the substrate with a second co-reactant reactive with the plurality of first intermediates to form a fourth oxide on the first portion of the substrate.

20. The method of claim 19, wherein the first precursor comprises a silicon precursor; the second precursor comprises a ruthenium precursor, a hafnium precursor, or an aluminum precursor; the first co-reactant comprises oxygen; the second co-reactant comprises O₃, and the reduction reactant comprises hydrogen.
